(19) United States
(12) Patent Application Publication
(10) Pub. No.: US 2007/0087645 A1
(43) Pub. Date: Apr. 19, 2007

(54) Manufacturing method of a display device

(76) Inventors: Akiko Tsujii, Tokyo (JP); Hideyuki Yamakawa, Tokyo (JP); Takao Shishido, Tokyo (JP)

Correspondence Address: SQUIRE, SANDERS & DEMPSEY L.L.P., 1 MARITIME PLAZA, SUITE 300, SAN FRANCISCO, CA, 94111, US

(21) Appl. No.: 11/502,241

(22) Filed: Aug. 9, 2006

(30) Foreign Application Priority Data
Oct. 19, 2005 (JP) 2005-304090

(51) Int. Cl. H01J 9/24

(52) U.S. Cl. 445/24

(57) ABSTRACT

A manufacturing method of a display device is disclosed. The display device can include: partition walls, a displaying part sectioned by the partition walls, a display function layer within the displaying part, and a substrate holding the partition walls, and the display function layer. The method can comprise forming at least one layer of the display function layer by an ink droplet supplied by transposition from an ink feed body, wherein the ink droplet is separated from the ink feed body after the ink droplet touches a region sectioned by the partition walls. After ink touched a region sectioned by partition walls, ink separates from ink feed body. Transposition of ink droplet forming the display layer is performed in this way. Therefore, even if a partition wall is not high, a partition wall can prevent ink droplet from scattering to other sections. Therefore, even if a partition wall does not include ink-repellent agent, a partition wall can prevent ink droplet from scattering to other sections.

### CROSS REFERENCE

This application claims priority to Japanese application number 2005-304090, filed on Oct. 19, 20005, which is incorporated by reference.

### BACKGROUND OF THE INVENTION

1. Field of the Invention

The present invention is related to a manufacturing method of display devices such as an organic electroluminescent element.

2. Description of the Related Art

In late years an organic electroluminescent element with the use of organic polymer system material has attracted attention. In manufacturing of this organic electroluminescent element, a thin film can be formed by wet process of applying ink of an organic polymer luminescent material. Therefore, manufacturing cost by a wet process can be lower than that by a dry process. In addition, in manufacture of a color display, patterning of luminescent material of plural colors is necessary. As patterning method of a display material such as a macromolecular luminescent material, an ink jet method (Japanese Patent Laid-Open No. 10-12377 Official Gazette) is illustrated.

However, there are the following problems in an ink jet method. A display layer is formed by jetting minute ink droplets of each color which are display materials from discharge nozzles in displaying parts sectioned by partition walls. The timing when an ink droplet separates from discharge nozzles is not constant. Therefore, a variation in a discharge rate of ink droplet occurs. In formation of the display layer, ink jet head is scanned. Or while fixing the head, a stage is scanned. When discharge velocity of an ink droplet varies, hitting position of an ink droplet is shifted on substrate. Because an ink hits a domain of an adjacent different color, color mixture occurs. Or the display layer cannot be formed in a predetermined region. Therefore, void in a pixel occurs.

By an ink jet method, a luminescent medium layer which is a display layer is formed in a displaying part. In this case, the minute ink droplet should be able to be discharged from a discharge jet. Therefore, an ink has to have little content of a luminescent medium material. Therefore it is necessary for height of luminescent medium ink applied on substrate to be higher than height of a partition wall so that the applied ink shows a predetermined function. A luminescent medium layer is formed by drying and solidification of applied ink. When height of the applied luminescent medium ink is more than height of a partition wall, it is necessary for height of a partition wall to be higher than predetermined height. Afterwards a luminescent medium layer is formed by drying and solidification of the luminescent medium ink. Then a difference in level between this luminescent medium layer and a partition wall occurs. This difference in level can be an obstacle to element formation.

In addition, when, like above, the height of an applied luminescent medium ink is higher than height of a partition wall, a partition wall may contain ink-repellent characteristics. However, a partition wall repels ink droplet when a partition wall has ink-repellent characteristics. Therefore, around a partition wall, the luminescent medium layer may not be formed.

In addition, in an ink jet method, plural ink droplets are discharged from discharge nozzles continuously in a display region of one block sectioned by partition walls. The later ink droplet is discharged in a different position from a top of the ink droplet discharged earlier. A luminescent medium layer is formed as aggregate of plural minute ink droplets by repetition of this process. For this case, the next ink droplet is not discharged in prescribed position when discharge velocity of ink droplet varies. Therefore, luminescent unevenness occurs in a luminescent medium layer formed in the displaying part.

A difference in level between a luminescent medium layer formed in displaying part sectioned by partition walls and the partition walls occurs. This difference in level is an obstacle to formation of an element. The present invention clears this obstacle. Besides, the present invention provides a manufacturing method of display devices such as electroluminescent elements without color mixture, void in a pixel and unevenness in light.

### SUMMARY OF THE INVENTION

A manufacturing method of a display device is developed.

A manufacturing method of a display device including a partition wall, a displaying part sectioned by the partition wall, a display function layer comprising a displaying part and a substrate holding the partition wall, the displaying part and the display function layer, wherein at least one layer among a display function layer is formed by an ink droplet supplied by transposition from an ink feed body, and wherein the ink droplet is separated from the ink feed body after the ink droplet touches a region sectioned by the partition walls.

After ink touched a region sectioned by partition walls, ink separates from ink feed body. Transposition of ink droplet forming the display layer is performed in this way. Therefore, even if a partition wall is not high, a partition wall can prevent ink droplet from scattering to other sections. Therefore, even if a partition wall does not include ink-repellent agent, a partition wall can prevent ink droplet from scattering to other sections.

### BRIEF DESCRIPTION OF DRAWINGS

FIG. 1A is a sectional view of one embodiment of an organic electroluminescent element of the present invention.

FIG. 1B is a cross-sectional view of an example of a substrate which can be used in the present invention.

FIGS. 2A, 2B, 2C and 2D are section views of partition walls which can be used in the present invention.

FIG. 3 is sectional extended figure of an organic electroluminescent element of one embodiment of the present invention.

FIG. 4 is a drawing of an example of the printing device and process that can be used in the present invention.

FIG. 5A, 5B and 5C are drawings of the other printing devices and processes that can be used in the present invention.

FIG. 6A, 6B, 6C and 6D are process drawings showing one embodiment of a manufacturing method of an embodiment of the present invention.

FIG. 7A, 7B, 7C and 7D are process drawings explaining transposition of an ink in the present invention in accordance with one embodiment.

In these drawings, 10 is an organic electroluminescent element; 11 is a substrate; 12 is a first electrode; 13 is a partition wall; 14 is an organic luminescent medium layer; 15 is a second electrode; 16 is a sealing body; 16a is an a sealing medium; 16b is a resin layer; 111 is a supporting body; 112 is an active layer; 113 is a gate insulator; 114 is a gate electrode; 115 is an interlayer dielectric; 116 is a drain electrode; 117 is a planarizing layer; 118 is a contact hole; 119 is a data line; 120 is a thin film transistor; 21 is a substrate; 22 is a first electrode; 23 is a partition wall; 30 is an organic electroluminescent element; 31 is a substrate; 32 is a first electrode; 33 is a partition wall; 34 is an organic luminescent medium layer; 35 is a second electrode; 36 is a sealing body: 36a is a sealing medium; 36b is a resin layer; 37 is a partition wall border; 38 is an overlap part; 41 is an ink tank; 42 is an ink chamber; 43 is an anilox roll; 44 is an ink; 45 is a relief printing plate; 46 is a printing cylinder; 47 is a stage; 48 is a substrate; 51 is a blanket cylinder; 52 is a silicone blanket; 53 is an ink layer; 53a is a pattern-shaped ink layer; 53b is an ink layer; 53c is an ink layer; 54 is a relief printing plate; 54a is a projection part (a convex part ); 55 is a substrate; 61 is a TFT substrate; 62 is a first electrode; 63 is a partition wall; 64 is a displaying part; 65 is an organic luminescent medium layer; 65a is a charge transport layer; 65b is an organic luminescent layer; 66 is a second electrode; 67 is an organic electroluminescent element; 71 is a substrate; 72 is a partition wall; 73 is an ink feeding body; and 74 is an ink droplet.

### DESCRIPTION OF THE PREFERRED EMBODIMENTS

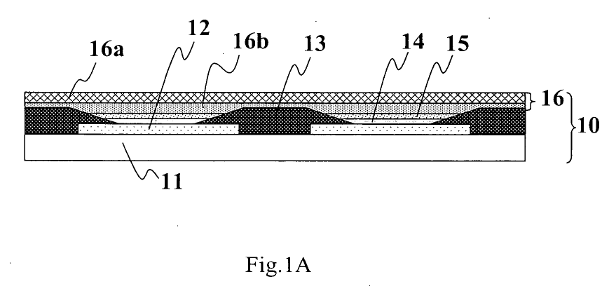

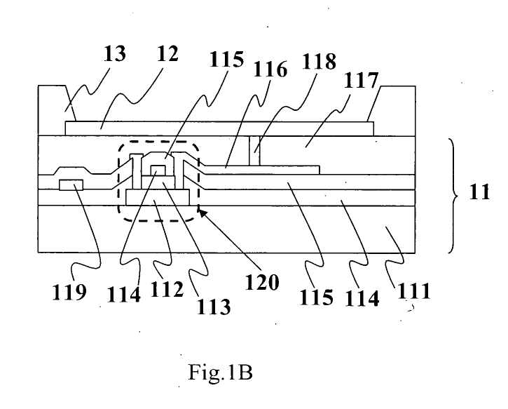

One embodiment of an organic electroluminescent element is explained as a display device. An organic electroluminescent element 10 which is a display device of the present invention has the following members (FIG. 1A): substrate 11, partition wall 13 formed on substrate, an organic luminescent medium layer 14 as a display function layer formed in a region sectioned by partition walls, first electrode 12 formed in the lower part of an organic luminescent medium layer, and second electrode 15 formed in the upper part of an organic luminescent medium layer.

An organic luminescent medium layer can be sandwiched between these electrodes. Sealing body 16 to protect an organic luminescent medium layer from external environment is formed on a second electrode. An organic luminescent medium layer comprises a charge transport layer and an organic luminescent layer.

### Substrate

Substrate 11 supports an organic electroluminescent element of the present invention. (FIG. 1A) An insulating property substrate which is superior in dimensional stability can be used as a substrate.

For example, the following substrates can be used as a substrate:

1. glass, quartz, plastic film or sheet such as polypropylene, polyether sulfone, polycarbonate, cyclo olefin polymers, polyarylate, polyamide, polymethyl methacrylate, polyethylene terephthalate and polyethylenenaphthalate;

2. the translucency substrate which the plastics film or sheet is laminated by only monolayer or the plural layers comprised of the following material:
metallic oxide such as oxidation silicon and alumina;
metal fluoride such as aluminium fluoride and magnesium fluoride;
metal nitrides such as silicon nitride and aluminum nitride;
metal acid nitride such as oxynitriding silicon;
macromolecule resin film such as acrylic resin, epoxy resin, silicone oil and polyester resin;
metallic foil, sheet or board made of aluminium or stainless, and

3. the non-translucency substrate which the plastic film or sheet is laminated by metal membrane such as aluminium, copper, nickel and stainless.

Depending on the direction which light comes out, translucency of substrate is selected.

It is necessary for a substrate comprising these materials to avoid entry of moisture to an organic electroluminescent element. In some embodiments, an inorganic film is formed on a substrate. In some embodiments, a fluorocarbon resin is applied to a substrate. It is desirable that exclusion of moisture and hydrophobic processing of a substrate are performed in this way. Particularly it is desirable to lower moisture content in a substrate and gas transmission coefficient to avoid entry of moisture to an organic luminescence medium.

In addition, as these substrates, the driving substrate that thin film transistor (TFT) is formed may be used if necessary. (FIG. 1B)

In the case that an organic electroluminescent element about the present invention is used as the organic electroluminescent element of active driving type, planarizing layer 117 can be formed on TFT 120. A bottom electrode (a first electrode 12) of an organic electroluminescent element can be on planarizing layer 117. And, by means of contact hole 118 in planarizing layer 117, a bottom electrode should be electrically connected to TFT. By reason of such a configuration, TFT is in a sufficiently electrical insulation state with an organic electroluminescent element.

TFT 120 and the upward organic electroluminescent element are supported with supporting body 111. It is desirable for mechanical intensity of supporting body 111 to be high. In addition, it is desirable for dimensional stability of supporting body 111 to be high. Material for the substrate can be used as material of supporting body 111.

For thin film transistor 120 on supporting body 111, any well-known thin film transistor can be used. In some embodiments, thin film transistor having the active layer that a source/drain region and a channel area are formed, the gate insulator and the gate electrode is exemplified. Configuration of thin film transistor is not limited to this configuration. By way of example, staggered type, reverse staggered type, top gate type and coplanar type can be used.

Active layer 112 can encompass many embodiments. It can be formed by inorganic semiconductor material such as amorphous Si, polycrystalline silicon, crystallite Si, cadmium selenide or organic semiconductor material such as thiophene oligomer, and poly(phenylene vinylene).

A manufacturing method of these active layers is exemplified below:

The method can include ion doping after laminating by plasma CVD technique of amorphous silicon. Can comprise the following processes: Formation of amorphous silicon by LPCVD method with the use of SiH₄ gas; formation of a poly Si by crystallization of amorphous silicon by solid phase epitaxy; and ion doping by ion implantation method.

The method (low temperature processing) comprising the following processes: Formation of amorphous silicon by LPCVD method with the use of Si₂H₆ gas (or formation of amorphous silicon by PECVD method with the use of SiH₄ gas.); annealing by laser such as excimer laser; formation of a poly Si by crystallization of amorphous silicon; and ion doping by ion doping method.

The method (high temperature processing) comprising the following processes: Laminating of a poly Si by low pressure CVD method or LPCVD method; formation of gate insulator by thermal oxidation more than 1,000 degrees Celsius; formation of gate electrode 114 of an n+ poly Si to the top; and ion doping by ion implantation method.

For gate insulator 113, a conventional gate insulator can be used. By way of example, SiO₂ formed by PECVD method or LPCVD method, SiO₂ provided by thermal oxidation of polysilicon film can be used.

For gate electrode 114, a conventional gate electrode can be used. Metal such as aluminum, copper, refractory metal such as titanium, tantalum and tungsten, a poly Si, silicide of refractory metal, or polycide can be used.

For thin film transistor 120, a single gate structure, a double gate structure, multiple gating configuration having gate electrodes more than three gate electrodes are exemplified. In addition, even LDD configuration and offset configuration are preferable. Even more particularly, thin film transistors of more than two thin film transistors may be placed on one pixel.

As for the display unit of an embodiment the present invention, thin film transistor has to function as a switching element of organic electroluminescent element. Drain electrode 116 of transistor and pixel electrode (a first electrode 12) of an organic electroluminescent element are connected electrically. Even more particularly, generally, for pixel electrode (a first electrode 12) for top emission configuration, it may be necessary for metal reflecting back light to be used.

Drain electrode 116 of thin film transistor 120 can be connected with pixel electrode (the first electrode 12) of an organic electroluminescent element by electric wiring. This electric wiring can be formed in contact hole 118 penetrating through planarizing layer 117.

Material of planarizing layer 117 is exemplified below. Inorganic materials such as SiO₂, spin-on-glass, SiN (Si₃N₄ and TaO (Ta₂O₅), organic materials such as polyimide resin, acrylic resin, photoresist material, and black matrix material can be used. Manufacturing methods such as spin coating, CVD and evaporation method can be selected depending on these materials. If necessary, a photosensitive resin is used as a planarizing layer 117, and contact hole 118 is formed by procedure of photolithography in position corresponding to thin film transistor 120. Or after having formed a planarizing layer on the entire surface, contact hole 118 is formed by dry etching or wet etching in position corresponding to thin film transistor 120. Contact hole 118 is buried by conductive material. Then contact hole is connected with pixel electrode electrically. A planarizing layer 117 should be able to cover up lower TFT, capacitor and electric wiring. So thickness of a planarizing layer should be several μm (for example 3 μm).

Insulating film 115 between layers is necessary. In FIG. 1B, data line 119 is also illustrated.

A figure of an example of the substrate which can be used for substrate 11 for active matrix driving type organic electroluminescent element is shown in FIG. 1B.

### First Electrode

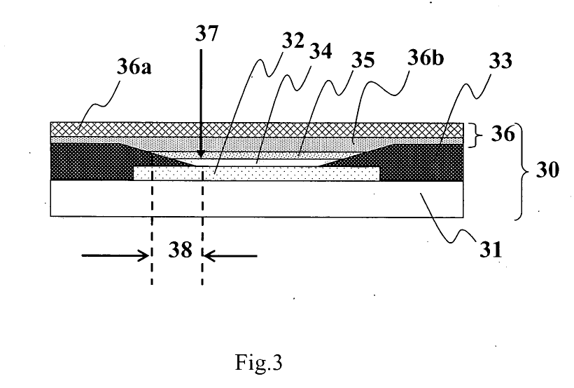

First electrode 12 (32) is layered on substrate 11 (31). Patterning of first electrode 12 (32) is performed if necessary. (FIG. 1A and 3)

Material of first electrode is described below:

A metal complex oxide such as ITO (indium tin complex oxide), IZO (indium zinc complex oxide) or AZO (zinc aluminium complex oxide);

metallic substances such as gold, platinum and chromium; and

the particle dispersion membrane which finely divided particles of the metallic oxide or the metallic substance is dispersed in epoxy resin or acrylic resin.

A single-layered body or a laminated material of the above described material can be used.

When a first electrode is an anode, it is desirable to select the material such as ITO that work function is high. In the case of so-called bottom emission configuration, it is necessary to select a transparent material as material of a first electrode.

Metallic substances such as copper or aluminium may be added as a supporting electrode to make electric wiring electrical resistance of a first electrode to be small if necessary.

For a formation method of a first electrode, the following methods can be used depending on material:

dry method such as resistance heating evaporation method, electron-beam evaporation technique, reactivity evaporation method, ion plating method and sputtering method; and

wet method such as the gravure process and screen printing.

For a patterning method of a first electrode, according to a material and a film formation method, existing patterning method such as mask evaporation method, photolithography method, wet etching method and dry etching method can be used.

When a substrate which TFT is formed is used, a first electrode is formed so that the first electrode is connected to lower TFT.

### Partition Wall

Partition walls section displaying part of a display device about the present invention. Partition wall 13 (33) of an organic electroluminescent element of the present invention is formed to section a light emitting area corresponding to a picture element. Unevenness of an edge of a first electrode is big. So a short circuit is caused unless this unevenness can be covered by an organic luminescent medium layer 14 (34). Therefore, an organic luminescent medium layer 14 (34) should be formed to cover an edge of a first electrode. (FIG. 1A and 3).

Therefore, in an organic electroluminescent element of an active matrix method that first electrode is pixel electrodes corresponding to each picture element, lattice shape is desirable for configuration of a partition wall. In an organic electroluminescent element of a passive matrix method of which first electrode is stripe shaped, a stripe shape partition wall is desirable.

For formation method of a partition wall, the same method as conventional method is preferable.

Inorganic film is formed on a substrate uniformly. After having masked with resist, dry etching is performed. Or after having laminated a light-sensitive resin on a subtrate, predetermined pattern is formed by photolithography method. Ink-repellent agent is added in a partition wall if necessary. Or a partition wall can have ink-repellent characteristics by irradiation by plasma and UV after partition wall formation.

Preferred height of a partition wall is 0.1 μm-10 μm. More preferably it is about 0.5 μm-2 μm.

When a partition wall is too high, a partition wall disturbs formation of a second electrode and a sealing body.

When a partition wall is too low, a partition wall cannot completely cover an end of first electrode. At the time of formation of an organic luminescent medium layer, a short circuit with adjacent pixel and color mixture can occur.

It is preferable for width of a partition wall to be more than 20 μm to prevent color mixture with adjacent pixel. More preferably it is more than 30 μm.

It is preferable for width of a partition wall to be equal to or less than 100 μm not to narrow a light emitting area.

If width of a partition wall is more than 20 μm, there is following effect.

Even if ink droplet of which volume is bigger than volume of the region sectioned by a partition wall is applied to the region, before ink droplet flows out to an adjacent section, drying of an ink droplet edge begins. As a result, color mixture does not occur. A region sectioned by a partition wall can hold sufficient amount of ink droplet. “Volume of the region” means a volume obtained by multiplying height of a partition wall to area of displaying part.

The case that width of a partition wall is more than 50 μm is explained below. Even if height of a partition wall is equal to or less than 1 μm and ink-repellent agent is not included in a partition wall, color mixture can be prevented sufficiently.

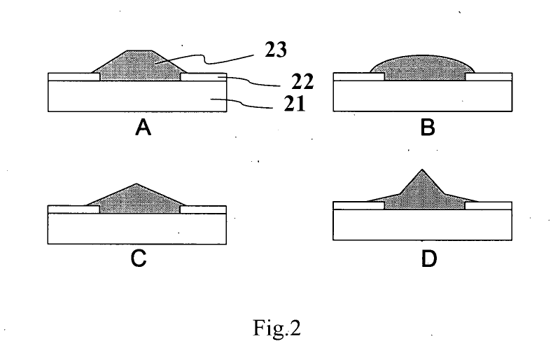

It is preferable for section of configuration of a partition wall to be a taper shape. As an embodiment, there are trapezoid, semi circle and the like shown in FIG. 2. Even triangular pyramid is preferable. Even the configuration that the middle of a slope of a partition wall curves is preferable. FIG. 2A illustrates partition wall 23 having a flat top with tapered, angular sides. FIG. 2B illustrates a “dome-shaped” partition wall 23 having curved top. FIG. 2C is the triangular or pyramid top illustration. FIG. 2D illustrates a partition wall 23 including sides tapering at a first angle extending into sides tapering at a second angle to form a triangular or pyramid shaped barrier in middle of the partition wall 23.

In the case of such a configuration, an edge of a partition wall overlaps an edge of the display function layer (the organic luminescent medium layer in FIG. 3) at part 38 shown in FIG. 3. Therefore, a change of thickness of the display function layer at border 37 of a partition wall is prevented. In other words, liquid does not gather at border 37 of a partition wall. Thickness of the display function layer does not vary at the upper part of displaying part. Thickness of the display function layer varies at overlap 38. This overlap is thinner than the display function layer formed in displaying part. Therefore, this overlap makes a difference in level between a partition wall and a displaying part mild. Therefore, other layers in the upper part of the display function layer can be formed uniformly. For example, in an organic electroluminescent element 30, second electrode can be formed uniformly. In addition, this overlap 38 prevents ink droplet from overflowing to an adjacent section (a picture element). When a border of a partition wall is perpendicular, ink droplet overflows at a time when ink droplet overflows. When a border of a partition wall is reverse taper configuration, ink droplet overflows at a time when it overflows.

Addition of ink-repellent agent is unfavorable because it causes a void in a pixel. According to the present invention, after ink touched a region sectioned by partition walls, ink separates from ink feed body. Transposition of ink droplet forming the display function layer is performed in this way. Therefore, even if a partition wall is not high, a partition wall can prevent ink droplet from overflowing to other sections. In addition, even if a partition wall does not include ink-repellent agent, a partition wall can prevent ink droplet from overflowing to other sections.

### Organic Luminescence Medium Layer

Organic luminescence medium layer 14 is formed next (FIG. 1A).

For organic luminescence medium layer 14 in the present invention, a single layer film or multilayer films including luminescent material can be formed.

Constitutional example in case of multilayer films is described below:

two layers comprising hole transport layer and electron transport property luminous layer, or hole transport-related luminous layer and electron transport layer; and

three layers comprising hole transport layer, luminous layer and electron transport layer.

Besides, function of hole (electron) injection and function of hole (electron) transportation may be separated if necessary. The layer which blocks transportation of hole (electron) may be inserted.

In addition, an organic luminescence layer in this specification means a layer including an organic luminescent material, and a charge transport layer such as a hole transport layer means a layer which is formed in order to improve luminous efficiency of other layer.

Representative examples of a hole transport material, comprising a hole transport layer, include copper phthalocyanine, metallophthalocyanine such as tetra(t-butyl) copper phthalocyanine, metal-free phthalocyanine, quinacridon chemical compound, aromatic amine type low molecular hole injection transportation material such as N,N′-di(1-naphthyl)-N,N′-diphenyl-1,1′-biphenyl-4,4′-diamine, 1,1-bis(4-di-p-tolylamino phenyl)cyclohexane, N,N′-diphenyl-N,N′-bis(3-methylphenyl)-1,1′-biphenyl-4,4′-diamine, macromolecule hole transport materials such as polyaniline (PANI), polythiophene, polyvinylcarbazole, mixture (PEDOT/PSS) with poly(3,4-ethylenedioxy thiophene) and polystyrene sulfonate, polythiophene oligomer material, and other existing hole transport materials.

The organic luminescent material can include low molecular type organic luminescent material and high molecular form organic luminescent material. Representative embodiments of luminescent materials include the following:

9,10-diaryl anthracenes, pyrene, coronene, perylene, rubrene, 1,1,4,4-tetra phenylbutadiene, tris(8-quinolinolate)aluminium complex, tris(4-carbinyl-8-quinolinolate) aluminium complex, bis(8-quinolinolate)zinc complex, tris(4-carbinyl-5-trifluoromethyl-8-quinolinolate)aluminium complex, tris(4-carbinyl-5-cyano-8-quinolinolate)aluminium complex, bis(2-carbinyl-5 -trifluoromethyl-8-quinolinolate) [4-(4-cyanophenyl)phenolate] aluminium complex, bis(2-carbinyl-5-cyano-8-quinolinolate) [4-(4-cyanophenyl)phenolate] aluminium complex, tris(8-quinolinolate)scandium complex, bis [8-(para-tosyl)aminoquinoline] zinc complex and cadmium complex, 1,2,3,4-tetraphenylcyclopentadiene, the pentaphenyl cyclopentadiene, poly-2,5-diheptyloxi-para-phenylenevinylene, chroma phosphorus type fluorescent substance, the perylene type fluorescent substance, the pyran type fluorescent substance, the anthrone type fluorescent substance, the porphyrin type fluorescent substance, the quinacridon type fluorescent substance, N, N′-dialkyl displacement quinacridon type fluorescent substance, the naphthalimido type fluorescent substance, N,N′-diaryl displacement pyrrolo pyrrole series fluorescent substance, low molecular system luminescent material such as phosphorescence fluor such as Ir chelate, high polymer materials such as poly arylene type, poly arylenevinylene type, poly fluorene, polyparaphenylene vinylene, polythiophene, police pyro, the material which the low molecular material is dispersed in these high polymer materials, or the material which inter-polymerization of the low molecular material with these high polymer materials was done, the material which low molecular system luminescent material is scattered in high polymer materials such as polystyrene, polymethyl methacrylate, polyvinylcarbazole, existing macromolecule/low molecular luminescent material.

Representative examples of an electron transport material include 2-(4-biphenyl)-5 -(4-t-butylphenyl)-1,3,4-oxadiazole, 2,5-bis(1-naphthyl)-1,3,4-oxadiazole, oxadiazoles, bis(10-hydroxybenzo [h] quinolinate) beryllium complex, triazole compound, and combinations thereof.

As is understood by one having ordinary skill in the art, a vacuum deposition can be for the deposition of these materials.

Film thickness of organic luminous medium layer can be lower than 1,000 nm whether organic luminous medium layer is single or plural layer(s), and preferably it is 50-150 nm.

As for the hole transport material of an organic electroluminescent element, covering of the surface protrusions of the substrate and first electrode is particularly important. Therefore, it is preferable to form a film of which thickness is about 50-100 nm.

For a formation method of organic luminescence medium layer 14, depending on the material comprising each layer, the following method can be used:

vacuum evaporation; coating methods or printing methods such as spin coat, spray coat, flexo, gravure, microgravure and intaglio offset; and ink jet method.

When solution of material comprising the organic luminescence medium layer is made, depending on the formation method, it is desirable to control vapor pressure, solids content rate and viscosity of solvent.

For solvent, water, dimethylbenzene, anisole, cyclohexanone, mesitylene, tetralin, cyclohexylbenzene, methyl benzoate, ethyl benzoate, toluene, ethanol, acetone, methyl ethyl ketone, methyl isobutyl ketone, methanol, isopropyl alcohol, ethyl acetate and butyl acetate can be used. Even mixed solvent comprising these materials is preferable.

In addition, to improve coating performance, it is preferred to mix an appropriate amount of additive such as detergent, antioxidant, viscosity modifier and UV absorber with the solution if necessary.

A drying method of application liquid is explained below.

Solvent is removed from application liquid not to influence luminescence property. As a method to remove solvent, removing by heating, removing under reduced pressure and removing by heating under reduced pressure can be used.

According to the present invention, at least one layer among the display function layers is formed by transposition of ink droplet from ink feed body.

Transposition of the ink droplet is described below. After the ink droplet touched a region sectioned by partition walls, ink droplet separates from the ink feed body. When a display device is an organic electroluminescent element, the display function layer is an organic luminescent medium layer.

At least one layer among the organic luminescent medium layer is formed by the following process.

Ink droplet including display function material touches a region sectioned by partition walls. Subsequently ink droplet separates from ink feed body. In this way ink droplet is supplied in displaying part. For example, a printing method is exemplified for such a feeding method of ink droplet.

Method to apply ink to the displaying part which is a picture element by a printing method is described below.

At first ink droplet is held by a printing plate. Then, ink droplet touches both of a printing plate and a substrate. Finally ink droplet is separated from a printing plate. And ink droplet transfers to a substrate. In other words, while ink droplet contacts with a printing plate or a substrate, it transfers. Therefore, ink droplet is not scattered to adjacent pixel and predetermined ink droplet can be applied to a predetermined picture element.

According to the present invention, preferably an organic luminescent layer included in organic luminescent medium layer 14 is formed by a printing method. More preferably, at least one layer among charge transport layers is further formed by a printing method. When charge transport layers are formed by the process of the present invention, patterning of charge transport layers can be performed without charge transport layers being connected to charge transport layers of adjacent pixel. In other words charge transport layers are not applied on a partition wall. Therefore, leak of current can be prevented. In addition, for color displays, different-colored inks are applied while the inks are separated from each other when an organic luminescent layer is formed by the process of the present invention. Even more particularly, if all layers of the organic luminescent medium layer are formed by a printing method, manufacturing process can be very simplified.

In one embodiment, charge transport layers and an organic luminescent layer included in an organic electroluminescent element of the present invention are formed by a printing method.

The printing method that can be used in the present invention is relief printing, gravure printing and planography (offset) printing.

For the substrate on which the organic luminescent medium layer is formed, it is often that glass and plastics film are used. Therefore, substrate is weak to local pressure. Therefore, substrate is easy to be damaged.

In addition, when ink transfers to a substrate by printing, ink is generally pushed into the air gap in the surface of substrate represented by papers. While controlling a supply of ink in this way, printing is performed. However, a substrate for a display device can be glass, plastics film and the like. Therefore, because face of substrate is smooth, a substrate does not absorb ink. Therefore the following phenomenon occurs.

When ink feed body supplies ink to substrate, ink feed body approaches substrate. Then size of the space for ink becomes small. Therefore ink overflows a region sectioned by partition walls. Therefore, an ink supply does not become constant.

Thus offset printing and relief printing using a plate of a resin or rubber are adopted. Then substrate is not damaged. In addition, when the printing plate which is ink feed body touches substrate, a printing plate transforms. Then while a printing plate pushes ink aside without ink being scattered, a printing plate touches substrate.

Even more particularly, for reasons of the following, it is preferable for cross-sectional shape of a partition wall to be taper shape.

There is space for ink pushed aside by ink feed body. In addition, because a contact area with ink is large, ink is hard to overflow to adjacent pixel.

Because film thickness can be formed uniformly, relief reversal offset printing is preferable.

### Relief Printing Method

For relief printing plate used for the formation of all or a part of an organic luminescent medium layer, water developable plastic plate is desirable. For a water developable photosensitive resin comprising such a resin printing plate, the type that hydrophilic polymer, monomer including unsaturated bonding so-called cross-linkable monomer and photoinitiator are component can be used. In this type, polyamide, polyvinyl alcohol and cellulose derivative are used as hydrophilic polymer. In addition, for example, methacrylate having vinyl bonding is used as cross-linkable monomer. For example, aromatic carbonyl compound is used as photoinitiator. Above all, a polyamide-based water developable photosensitive resin is preferred from an aspect of printability. A printing method using a resin printing plate is suitable for a printing method of a printing plate touching a substrate.

When a partition wall is lattice shaped, ink droplet can be supplied using a printing plate having stripe projection part. In this case, only one direction positioning should be performed. Therefore, a process can be very simplified. Height of projection part of a printing plate is several hundred μm. Besides, projection part of a printing plate has elastic properties. A partition wall of substrate is several μm at most. Therefore, projection part of a printing plate can get over a partition wall sufficiently. Therefore, printing is easily performed.

As a printer for the formation of all or a part of an organic luminescent medium layer, relief printing machine for printing to flat plate can be used. By way of example only, printer as shown in the following is desirable.

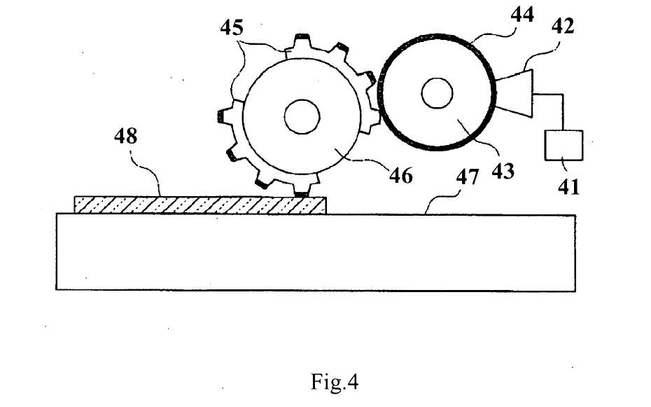

A schematic illustration of printer is shown in FIG. 4. This manufacturing apparatus has ink tank 41, ink chamber 42, anilox roll 43 and plate cylinder 46 which plastic plate 45 was attached.

An organic luminescent medium ink diluted with solvent is accommodated in ink tank 41. Organic luminescent medium ink is sent into ink chamber 42 from ink tank 41. Anilox roll 43 rotates close against an ink supply of ink chamber 42 and plate cylinder 46.

Organic luminescent medium ink 44 supplied from ink chamber is held uniformly on anilox roll surface by using a doctor blade while anilox roll 43 is rotating. Then, the organic functional ink on anilox roll surface is transferred with uniformity on a convex part of a plastic plate attached on a plate cylinder. Substrate 48 is fixed on a substrate fixing stage which is slidable (stage 47). While a positioning mechanism is positioning substrate 48, substrate 48 is moved to a printing staring point. Even more particularly, while a convex part of plastic plate is close against a substrate, plastic plate moves in correspondence with rotation of a plate cylinder. Pattern-shaped ink droplet is transferred in predetermined position of a substrate.

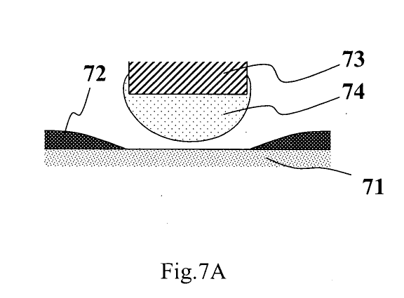

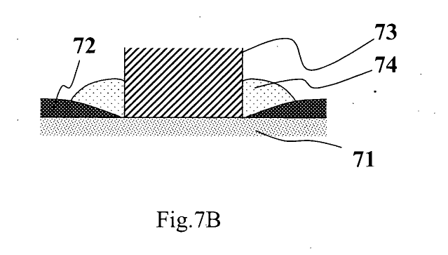

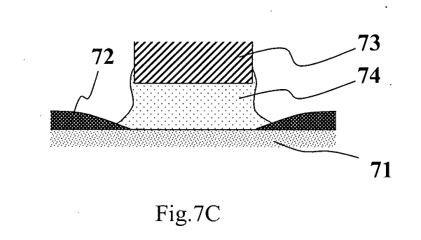

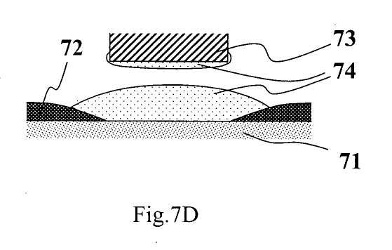

Ink droplet 74 is supplied from ink feed body 73 to a region sectioned by partition walls 72. (FIG. 7A-7D)

Ink droplet touches a region sectioned by the partition walls. (FIG. 7C)

Afterwards, ink droplet separates from ink feed body. (FIG. 7D)

However, a size of ink droplet is limited. When distance between ink feed body and substrate 71 is longer than a size of ink droplet, transposition of ink droplet does not occur. Even if transposition of ink droplet occurs, after separation of ink droplet from ink feed body, ink droplet touches substrate 71. Then ink droplet cannot be applied to a desired display region. In addition, ink droplet is scattered by an impact at the time of ink droplet transposition.

Therefore it is adjusted so that ink feed body touches substrate before transposition of ink droplet. (FIG. 7B) Then transposition of ink droplet is performed surely.

Ink droplet touches a region sectioned by partition walls. (FIG. 7C)

Afterwards ink droplet separates from the ink feed body. (FIG. 7D)

Before transposition of ink droplet, ink feed body should touch “substrate”. Here, “substrate” means not only “a display region” but also “the part which is near substrate” such as tops of a partition wall.

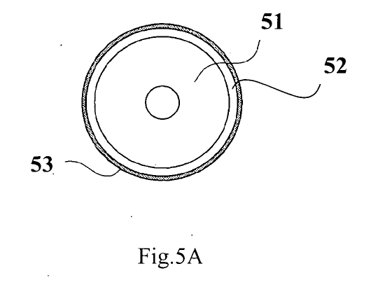

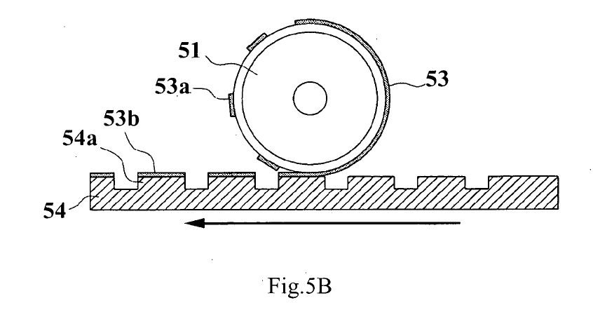

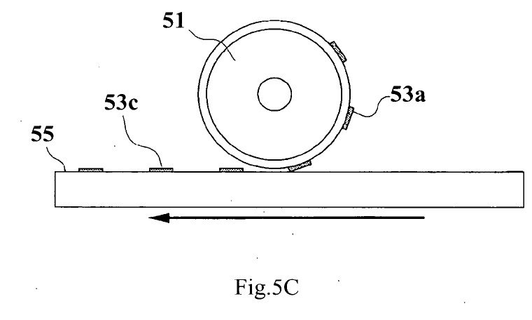

An example of a relief reversal offset printer which can be applied to the formation of all or a part of an organic luminescent medium layer is shown in FIGS. 5A and 5B.

Relief reversal offset printer has a blanket which supports an ink layer, an ink supply (not shown in figures) which supplies an ink on the blanket and a relief printing plate which removes an useless part of the ink layer on the blanket.

In addition, a substrate is placed on the stage which is under a blanket. A substrate is moved in accordance with printing speed.

Blanket comprises blanket cylinder 51 and silicone blanket 52 wound around blanket cylinder 51.

Ink for ink layer 53 is applied to effective surface of the silicone blanket installed in a blanket cylinder by the ink feed means that is not illustrated.

Ink layer 53 is formed by drying ink for ink layer 53 (FIG. 5A).

Subsequently blanket cylinder 51 rotates. Relief printing plate 54 on which negative pattern (non-printing area) is formed is attached to silicone blanket 52 by pressure. The stage that relief printing plate is fixed moves in accordance with rotation of a blanket cylinder. At this time, ink layer 53b which is attached by pressure to convex part 54a of relief printing plate is removed from blanket, and this part of the ink layer 53b is transferred to a convex part of relief printing plate. Desired pattern 53a of an ink layer is formed on blanket (FIG. 5B).

Blanket cylinder 51 rotates next. Substrate 55 attaches by pressure to silicone blanket 52. The stage on which a substrate is fixed moves in accordance with rotation of a blanket cylinder. At this time, pattern-shaped ink layer 53a on silicone blanket is transferred to a substrate. In this way, ink layer 53c is formed on substrate 55 (FIG. 5C).

### Second Electrode

Second electrode 15 (35) can be formed next as illustrated by FIG. 1A and 3. When a second electrode is a cathode, the material discussed below can be used.

The material can be of a type with high electron injection efficiency to an organic luminescent medium layer 14 and low work function.

In some embodiments, second electrode 15 (35) can include a metal such as Mg, Al, Yb and combination of the same.

In addition, the following layer stack may be put in a boundary surface of the luminescent medium. The layer stack is that with chemical compound of about 1 nm thicknesses such as Li and oxidation Li, LiF and Al and Cu of stability and/or high conductivity. Stability should be balanced with electron injection efficiency. Therefore an alloy system may be used. Alloy of more than one kind of metal such as Li, Mg, Ca, Sr, La, Ce, Er, Eu, Sc, Y, and Yb that have a low work function, and metallic element such as Ag, Al, and Cu which are stable can be used. In some embodiments, alloy such as MgAg, AlLi, and CuLi can be used.

It is desirable to select a transparent material in so-called top emission construction so as to allow visible radiation to come out of the second electrode side. In this case, Li and Ca of a low work function are provided with thin measurements. Metal complex oxide such as ITO (indium tin complex oxide), IZO (indium zinc complex oxide) and AZO (zinc aluminium complex oxide) may be laminated thereafter. In addition, a little metal doping such as Li and Ca of a low work function can be performed to organic luminous medium layer 14, and metal compound such as ITO may be laminated.

Depending on the material, for the formation of the second electrode, methods such as resistance heat coating by vaporization, electron beam evaporation, reactive deposition, ion plating and sputtering can be used.

For the second electrode, thickness of about 10 nm-1,000 nm is desirable.

In addition, when the second electrode is transparent electrode layer and is made of metallic substances such as Ca or Li, it is desirable for the thickness of the second electrode to be 0.1-10 nm.

### Sealing Body

As organic electroluminescent element, organic luminous layer is sandwiched between electrodes, and it can emit light by applied electric current. However, organic luminous layer deteriorates easily by means of atmospheric moisture and oxygen. Thus a seal to intercept organic luminous layer and the like from the outside is usually provided.

A sealing body 16(36) is explained below.

By way of example only, the substrate that the first electrode, the organic luminescent medium layer including organic luminous layer and the second electrode are formed is prepared. Resin layer 16b (36b) is provided over a sealing medium 16a (36a). A sealing medium 16a (36a) is stuck on the substrate by means of resin layer 16b (36b).

For a sealing medium 16a (36a), it is necessary for transmissivity of moisture and oxygen to be low.

In addition, as a material of the sealing medium, ceramics such as alumina, silicon nitride and boron nitride, glass such as no-alkali glass and alkali glass, quartz, metallic foil such as aluminium and stainless, and humidity resistance film are exemplified.

By way of example, the following humidity resistance film is exemplified:
the film which is formed of SiOx by CVD method on both sides of a plastic substrate; the film which laminated the film that transmissivity of moisture and oxygen is small and hydrophilic film; and the film which water absorption agent is applied on a film that transmissivity of moisture and oxygen is small.

It is preferable for water vapor permeation rate of the humidity resistance film to be less than 10⁻⁶ g/m²/day.

For example, for resin layer 16b, the following materials can be used:

A photo-curing adhesive property resin, a heat curing adhesive property resin, 2 fluid hardening adhesive property resin comprising an epoxy type resin, acrylic resin, silicone oil and the like, acrylic resin such as ethylene ethylacrylate (EEA) polymer, vinyl resins such as ethylene vinyl acetate (EVA), thermoplastic resin such as polyamide, a synthetic rubber, thermoplasticity adhesive property resins such as acid denatured substances of polyethylen or polypropylene.

An example of method to form resin layer on a sealing medium is shown below:

solvent solution method, pushing out laminate method, fusion/hot melt method, calender method, discharge jet application method, screen printing, vacuum laminate method and heated roll laminate method.

A material having hygroscopicity and a property to absorb oxygen can be incorporated into adhesive if necessary.

Depending on size and configuration of sealed organic electroluminescent display unit, thickness of resin layer installed in a sealing medium is fixed. As for the thickness of resin layer, about 5-500 μm are desirable.

In a sealing room, a substrate with the first electrode, the organic luminous medium layer including organic luminous layer and the second electrode is affixed to a sealing body 16 (36).

When it is two layers construction consisting of a sealing medium and resin layer of thermoplastic resin, contact bonding should be performed only by heating roller.

In the case of a heat curing type adhesive resin, it attaches by pressure by heating roller. And a heat curing type adhesive resin is heated, and is hardened.

At first, in the case of a photo-curing-related adhesive resin, it is sealed by pressure by roller. And a photo-curing-related adhesive resin is stiffened by irradiating a light.

In addition, in the above described example, resin layer may be formed on a sealing medium. However, after having formed resin layer on a substrate, it may be stuck with a sealing medium.

Before sealing by means of a sealing body, inorganic thin film may be formed. By way of example only, as passivation film, silicon-nitride film of which film thickness is 150 nm is formed by CVD method. In addition, a sealing body consisting of inorganic thin film can be formed.

After ink touches a region sectioned by partition walls, ink separates from ink feed body. Transposition of ink droplet forming the display layer is performed in this way. Therefore, even if a partition wall is not high, a partition wall can prevent ink droplet from scattering to other sections. Therefore, even if a partition wall does not include ink-repellent agent, a partition wall can prevent ink droplet from scattering to other sections.

In addition, ink droplet of which quantity is bigger than regional volume sectioned by partition walls is supplied. Therefore, even if density of display material included in ink droplet is low, a display layer of which thickness is enough to show a display function can be obtained.

Even more particularly, even if height of applied ink droplet is higher than height of a partition wall, after ink touches domain sectioned by partition walls, ink separates from ink feed body. Transposition of ink droplet forming the display function layer is performed in this way. Therefore, ink droplet is not scattered outside a partition wall. Transposition of ink droplet is performed once for one section. Therefore, a variation of thickness of the display function layer can be controlled. Even more particularly, ink feed body touches substrate before transposition of ink droplet. Therefore, transposition of ink can be performed. In addition, void in a pixel or ink scattering can be prevented.

Based upon the foregoing, the present invention clears an obstacle to formation of an element due to a difference in level between display function layer formed in displaying part sectioned by partition walls and the partition walls. And the present invention provides manufacturing method of display devices such as an organic electroluminescent element without color mixture, void in a pixel and luminescent unevenness.

### EXAMPLE 1

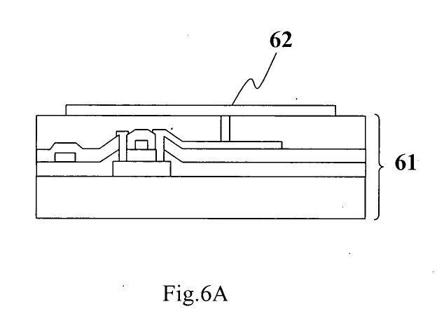

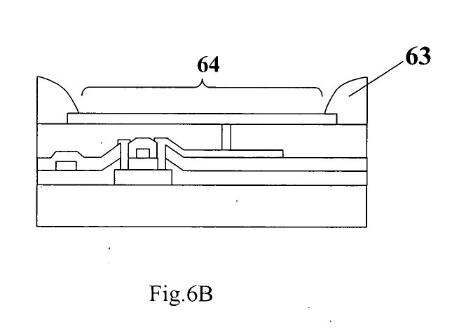

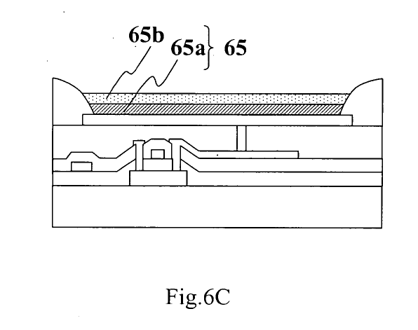

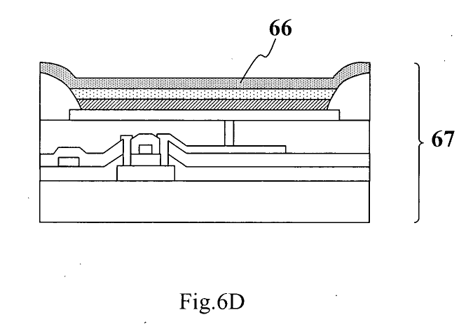

One embodiment of the invention is explained in FIG. 6 and FIG. 7.

As a substrate, TFT substrate 61 was used. TFT substrate 61 is explained below. Glass plate was used as a supporting body. The size of a supporting body was 300 mm square. This supporting body is for two panels. The picture element number of one panel was 320*240.

First electrode 62 corresponding to TFT was formed on this substrate. (FIG. 6A)

The photosensitivity polyimide resin of which thickness was 1 μm was formed on substrate by a slit coat method. Displaying part corresponding to a light emitting area was formed by exposure/developing. In addition, lattice shaped partition wall 63 of which width was 30 μm was formed.

The cross-sectional shape of a partition wall was configuration of semiellipse. In addition, the hem of a partition wall was like slow slope. (FIG. 6B)

Ink of polymer hole transport material was applied to displaying part 64 sectioned by partition walls by relief printing. Charge transport layer 65a of which thickness was 50 μm was formed by drying this ink. A polythiophene derivative (PEDOT/PSS) was used for a macromolecular hole transport material. Ink was made by dispersing this macromolecular hole transport material in water.

A polyamide system water developable light-sensitive resin was used as a printing plate.

The ink droplet for a charge transport layer touched a region sectioned by partition walls. (FIG. 7B)

Afterwards the ink droplet separated from a printing plate. (FIG. 7D)

Therefore, the ink droplet did not overflow to adjacent pixel.

In addition, after a printing plate touched a region sectioned by partition walls, this transposition of ink droplet was performed.

This process is shown in FIG. 7A, 7B, 7C and 7D.

Subsequently organic luminescent materials of three colors of RGB were applied on charge transport layer 65a by relief printing. Organic luminescent layer 65b of which thickness was 80 μm was formed by drying this material. Organic luminescent medium layer 65 including a charge transport layer and an organic luminescent layer was formed in this way. (FIG. 6C)

For formation of this organic luminescent layer, the following organic luminescence ink was used. In addition, a polyamide system water developable light-sensitive resin was used as a printing plate.

Red luminescence ink (R): The solution that a poly fluorene system derivative dissolves in a toluene. The concentration of a poly fluorene system derivative was 1% by weight. (red luminescence material made in chemical Sumitomo Corporation: commercial name Red1100)

Green emission ink (G): The solution that a poly fluorene system derivative dissolves in a toluene. The concentration of a poly fluorene system derivative was 1% by weight. (green emission material made in chemical Sumitomo Corporation: commercial name Green1300)

Blue luminescence ink (B): The solution that a poly fluorene system derivative dissolves in a toluene. The concentration of a poly fluorene system derivative was 1% by weight. (blue luminescence material made in chemical Sumitomo Corporation: commercial name Blue1100)

Forming process of the organic luminescent medium layer is described below.

Ink droplet touched a region sectioned by partition walls. Thereafter, ink droplet separated from a printing plate. Transposition of ink droplet was performed in this way. Therefore, ink droplet did not overflow to adjacent pixel. In addition, after a printing plate touched a region sectioned by partition walls, this transposition was performed. The organic luminescent layer of which width was about 8 μm was formed on a partition wall edge. Therefore, the organic luminescent layer of which thickness was nonuniform was not formed on a border of a partition wall. The border was displaying part.

The organic luminescent layer corresponding to each displaying part was formed by one ink feeding. Therefore, time for ink feeding was short. In addition, a constant amount of ink droplet was able to be supplied in a block.

By resistance heating evaporation method in vacuum, second electrode 66 was formed on an organic luminescent medium layer which was formed by relief printing. The second electrode 66 included the Ca of which thickness was 5 μm and the Al of which thickness was 100 nm. (FIG. 6D)

Height of a partition wall was low (1 μm). In addition, there was not a difference in level between the partition wall and the organic luminescent medium layer. Therefore, the disconnection of the second electrode did not occur.

This active matrix type organic electroluminescent element 67 of which picture element number was 76800 was sealed by a glass cap. The first electrode was used as an anode. The second electrode was used as a cathode. And this organic electroluminescent element was made to emit light. Luminescence was observed from the first electrode side.

The following defect was not observed: cross talk due to current leak, color mixture and void in a pixel due to poor patterning of an organic luminescent layer, and unevenness of a color due to nonuniformity of thickness of the organic luminescent medium layer and second electrode.

### EXAMPLE 2

The height of a partition wall was 0.8 μm. An organic electroluminescent element was manufactured by the same method as example 1 other than the height of the partition wall.

This active matrix type organic luminescence element was sealed by a glass cap. The first electrode was used as an anode. The second electrode was used as a cathode. And this organic electroluminescent element was made to emit light. Luminescence was observed from the first electrode side.

The following defect was not observed: cross talk due to current leak, color mixture and void in a pixel due to poor patterning of an organic luminescent layer and unevenness of a color due to nonuniformity of thickness of the organic luminescent medium layer and the second electrode.

### EXAMPLE 3

The substrate on which partition walls were formed by the same method as example 1 was prepared. Subsequently an organic luminescent medium layer including a charge transport layer and an organic luminescent layer was formed by relief reversal offset printing in displaying part sectioned by partition walls. In this case, after the ink droplet which formed an each layer touched a region sectioned by partition walls, the ink droplet separated from a blanket. Therefore, the ink droplet did not overflow to adjacent pixel. After a partition wall touched a blanket partially, the transposition of this ink was performed.

Polyaniline was used as a macromolecular hole transport material. Propanol was used as solvent. Ink was made of the macromolecular hole transport material and the solvent. Charge transport layers were formed with this ink.

In addition, the poly fluorene which was a macromolecular luminescent material was used as an organic luminescent material. CHB (cyclohexylbenzene) was used as solvent. Ink was made of the organic luminescent material and the solvent. An organic luminescent layer was formed with this ink.

Afterwards a second electrode was formed same as example 1. This active matrix type organic electroluminescent element was sealed by a glass cap. The first electrode was used as an anode. The second electrode was used as a cathode. And this organic electroluminescent element was made to emit light. Luminescence was observed from the first electrode side.

The following defect was not observed: cross talk due to current leak, unevenness of a color due to nonuniformity of thickness of the organic luminescent medium layer and second electrode; and the organic luminescence ink droplet corresponding to a part of section did not touch substrate. Therefore, patterning failure of the organic luminescent medium layer occurred. And void in a pixel was observed partially.

### COMPARATIVE EXAMPLE 1

The substrate on which partition walls were formed same as example 1 was prepared. Subsequently ink-shaped macromolecular hole transport material was applied to a displaying part sectioned by partition walls by an ink jet method. The charge transport layer of which thickness was 50 nm was formed by drying this ink. A polythiophene derivative (PEDOT) was used for macromolecular hole transport material. Ink was made by dispersing this macromolecular hole transport material in water.

Subsequently an organic luminescent layer of which thickness was 80 nm was formed on the charge transport layer by an ink jet method. The organic luminescent medium layer including a charge transport layer and an organic luminescent layer was made in this way.

In formation of this organic luminescent layer, the following organic luminescence ink was used. In an ink jet method, plural minute droplets were discharged in a block. And aggregate of ink droplet was formed.

Red luminescence ink (R): The solution which dissolved a spiro system derivative in a toluene. The concentration of a spiro system derivative was 1% by weight. (red luminescence material made in Merck Co.: commercial name CR01)

Green emission ink (G): The solution which dissolved a spiro system derivative in a toluene. The concentration of a spiro system derivative was 1% by weight. (green emission material made in Merck Co.: commercial name CG02)

Blue luminescence ink (B): The solution which dissolved a spiro system derivative in a toluene. The concentration of a spiro system derivative was 1% by weight. (blue luminescence material made in Merck Co.: commercial name CB02T)

Afterwards a second electrode was formed same as example 1.

This active matrix type organic electroluminescent element was sealed by a glass cap.

The first electrode was used as an anode. The second electrode was used as a cathode. And this organic electroluminescent element was made to emit light. Luminescence was observed from the first electrode side.

The following defect was not observed: cross talk due to current leak.

However, color mixture and unevenness of a color in 15% area were observed. It was thought that this phenomenon occurred because minute droplets overflowed to adjacent pixel due to a low partition wall.

What is claimed is:

1. A manufacturing method of a display device including partition walls, a displaying part sectioned by the partition walls, a display function layer within the displaying part, and a substrate holding the partition walls and the display function layer, the method comprising:
forming at least one layer of the display function layer by an ink droplet supplied by transposition from an ink feed body,
wherein the ink droplet is separated from the ink feed body after the ink droplet touches a region sectioned by the partition walls.

2. The manufacturing method of a display device according to claim 1, wherein a layer of the display function layer in one section is formed by one transposition of the ink droplet.

3. The manufacturing method of a display device according to claim 1, wherein a volume of the ink droplet supplied to the displaying part by one transposition of the ink droplet is bigger than a volume of a region sectioned by the partition walls.

4. The manufacturing method of a display device according to claim 1, wherein the displaying part is line shaped.

5. The manufacturing method of a display device according to claim 1, wherein the ink feed body is a printing plate of which printing area corresponds to the displaying part.

6. The manufacturing method of a display device according to claim 1, wherein the ink feed body touches the substrate before the transposition of the ink droplet.

7. The manufacturing method of a display device according to claim 1, wherein the display function layer is an luminescent medium layer.

8. The manufacturing method of a display device according to claim 1, wherein the display function layer is a dispersing colored layer.
